(19) United States
(12) Patent Application Publication
(10) Pub. No.: US 2023/0083062 A1
(43) Pub. Date: Mar. 16, 2023

(54) TEMPERATURE STIMULUS PRESENTATION DEVICE AND METHOD

(71) Applicant: Nippon Telegraph and Telephone Corporation, Tokyo (JP)

(72) Inventors: Arinobu NIIJIMA, Musashino-shi, Tokyo (JP); Toki TAKEDA, Musashino-shi, Tokyo (JP); Takafumi MUKOUCHI, Musashino-shi, Tokyo (JP); Takashi SATO, Musashino-shi, Tokyo (JP)

(21) Appl. No.: 17/795,040

(22) PCT Filed: Feb. 7, 2020
(86) PCT No.: PCT/JP2020/004748

§ 371 Date: Jul. 25, 2022

(51) Int. Cl. G06F 3/01

(52) U.S. Cl. CPC G06F 3/01; H01L 35/30

(57) ABSTRACT

A temperature stimulus presentation device 100 that uses a Peltier element 10 to present a temperature stimulus includes a human body detection unit 20 that detects contact of a part of a human body H with a heat dissipation plate 12 or a heat absorption plate 11 of the Peltier element 10 based on a change in an electrostatic capacitance between the heat dissipation plate 12 and the heat absorption plate 12, and a temperature stimulus generation unit 30 that supplies a current to the Peltier element 10 when an amount of the electrostatic capacitance change exceeds a threshold.

### TECHNICAL FIELD

The present invention relates to a temperature stimulus presentation device using a Peltier element and a method therefor.

### BACKGROUND ART

A tactile display that uses a Peltier element to present a temperature stimulus has been studied. As methods for presenting the temperature stimulus, there are two methods, i.e., a method which causes a current to constantly flow in the Peltier element and continues of present a temperature and a method which uses a touch sensor or the like to detect a case where the temperature stimulus is required and presents the temperature stimulus (see, e.g., PTL 1).

### CITATION LIST

### Patent Literature

[PTL 1] Japanese Patent No. 4537932

### SUMMARY OF THE INVENTION

### Technical Problem

However, the method which causes the current to constantly flow consumes increased power. Meanwhile, the method which detects the case where the temperature stimulus is required needs the touch sensor. Thus, each of the conventional temperature stimulus presentation methods has a problem of the increased power consumption or the increased number of components.

The present invention has been achieved in view of this problem, and an object thereof is to provide a temperature stimulus presentation device that consumes reduced power and has a smaller number of components and a method therefor.

### Means for Solving the Problem

The essence of a temperature stimulus presentation device according to an aspect of the present invention is being a temperature stimulus presentation device that uses a Peltier element to present a temperature stimulus, the device including: a human body detection unit that detects contact of a part of a human body with a heat dissipation plate or a heat absorption plate of the Peltier element based on a change in an electrostatic capacitance between the heat dissipation plate and the heat absorption plate; and a temperature stimulus generation unit that supplies a current to the Peltier element when an amount of the electrostatic capacitance change exceeds a threshold.

The essence of a temperature stimulus presentation method according to the aspect of the present invention is being a temperature stimulus presentation method to be implemented by the temperature stimulus presentation device described above, the method including: a human body detection step of detecting contact of a part of a human body with a heat dissipation plate or a heat absorption plate of a Peltier element based on a change in an electrostatic capacitance between the heat dissipation plate and the heat absorption plate; and a temperature stimulus generation step of supplying a current to the Peltier element when an amount of the electrostatic capacitance change exceeds a threshold.

### Effects of the Invention

According to the present invention, it is possible to provide a temperature stimulus presentation device that consumes reduced power and has a smaller number of components and a method therefor.

### BRIEF DESCRIPTION OF DRAWINGS

FIG. 1 is a block diagram illustrating an example of a functional configuration of a temperature stimulus presentation device according to an embodiment of the present invention.

FIG. 2 is a diagram schematically illustrating a structure of a Peltier element illustrated in FIG. 1.

FIG. 3 is a diagram illustrating an example of an output from a human body detection unit illustrated in FIG. 1.

FIG. 4 is a diagram illustrating a flow chart representing a processing procedure in a temperature stimulus presentation method to be implemented by the temperature stimulus presentation device illustrated in FIG. 1.

### DESCRIPTION OF EMBODIMENTS

A description will be given below of an embodiment of the present invention with reference to the drawings. In the plurality of drawings, the same components are given the same reference numerals, and a description thereof is not repeated.

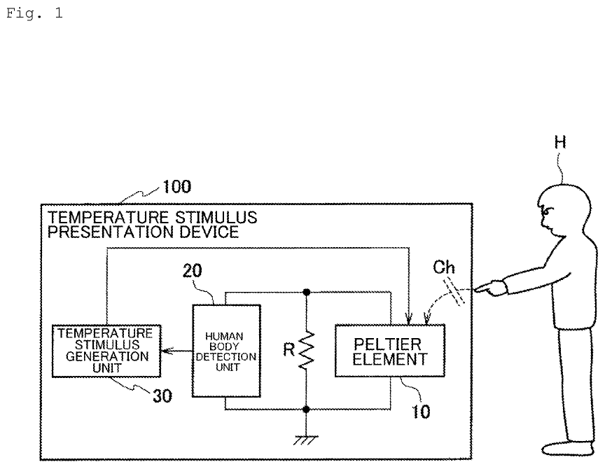

FIG. 1 is a block diagram illustrating an example of a functional configuration of a temperature stimulus presentation device according to the embodiment of the present invention. A temperature stimulus presentation device 100 illustrated in FIG. 1 presents a temperature stimulus when a human H touches the temperature stimulus presentation device 100 with a fingertip.

Note that FIG. 1 illustrates only a main portion forming the present invention. Illustration of a typical configuration such as a power source is omitted.

The temperature stimulus presentation device 100 includes a Peltier element 10, a human body detection unit 20, and a temperature stimulus generation unit 30. The Peltier element 10 is a type of a typical plate-like semiconductor thermoelectric element using a Peltier effect. The Peltier element 10 will be described later in detail.

The human body detection unit 20 detects contact of a part of a human body with a heat dissipation plate or a heat absorption plate of the Peltier element 10 based on a change in an electrostatic capacitance between the heat dissipation plate and the heat absorption plate. The human body detection unit 20 can be formed of a CR oscillation circuit including the electrostatic capacitance between the heat dissipation plate and the heat absorption plate of the Peltier element 10 and a resistor R.

The temperature stimulus generation unit 30 supplies a current to the Peltier element 10 when an amount of the electrostatic capacitance change between the heat dissipation plate and the heat absorption plate of the Peltier element exceeds a threshold. The Peltier element 10 performs both of a heat absorbing operation and a heat generating operation by being supplied with the current.

As described above, the temperature stimulus presentation device 100 according to the present embodiment is the temperature stimulus presentation device that uses the Peltier element 10 to present a temperature stimulus and includes the human body detection unit 20 that detects the contact of the part of the human body with the heat dissipation plate or the heat absorption plate of the Peltier element 10 based on the electrostatic capacitance change between the heat dissipation plate and the heat absorption plate, and the temperature stimulus generation unit 30 that supplies the current to the Peltier element when the amount of the electrostatic capacitance change exceeds the threshold. Thus, the Peltier element 10 functions as a sensor that detects a case where a temperature stimulus is to be presented, and therefore a component for detecting the case is unnecessary. In addition, since the current is supplied to the Peltier element 10 when the part of the human body comes into contact therewith, it is unnecessary to cause the current to constantly flow. Therefore, it is possible to reduce power consumption. In other words, the temperature stimulus presentation device 100 can provide a temperature stimulus presentation device that consumes reduced power and has a smaller number of components.

(Peltier Element)

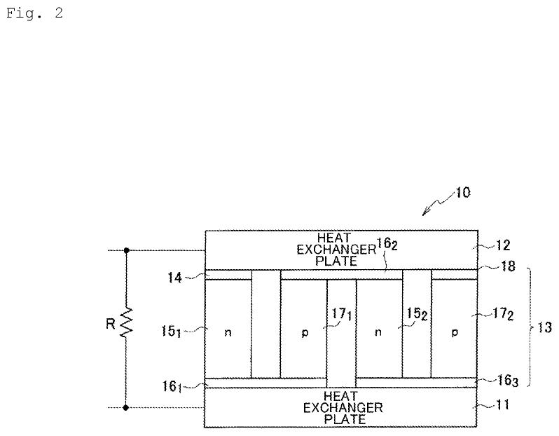

FIG. 2 is a diagram schematically illustrating an example of a configuration of the Peltier element 10. The Peltier element 10 includes a thermoelectric module 13 and the two heat exchanger plates 11 and 12.

The Peltier element 10 is formed of the thermoelectric module 13 held between the two heat exchanger plates 11 and 12 to transfer heat from the one heat exchanger plate 11 to the other heat exchanger plate 12. The heat exchanger plates 11 and 12 are formed of, e.g., a copper material or the like having a relatively high heat conductivity.

The thermoelectric module 13 includes a negative electrode 14, n-type thermoelectric materials 15₁ and 15₂, common electrodes 16₁, 16₂, and 16₃, p-type thermoelectric materials 17₁ and 17₂, and a positive electrode 18. An insulating layer (not shown) provides insulation between each of the heat exchanger plates 11 and 12 and each of the electrodes (the positive electrode 18, the negative electrode 14, and the common electrodes 16₁, 16₂, and 16₃).

To the positive electrode 18, a positive electrode of a power source (not shown) is connected, while a negative electrode of a power source 7 is connected to the negative electrode 14. As a result, holes in the p-type thermoelectric materials 17₁ and 17₂ move from the heat exchanger plate 12 toward the heat exchanger plate 11. In addition, electrons in the n-type thermoelectric materials 15₁ and 15₂ also move from the heat exchanger plate 12 toward the heat exchanger plate 11. Since heat around the heat exchanger plates 11 and 12 is transferred by the holes and electrons that serve as carriers, in this example, the heat exchanger plate 12 serves as the heat absorption plate, while the heat exchanger plate 11 serves as the heat dissipation plate. The heat exchanger plates 11 and 12 may be hereinafter referred to also as the heat absorption plate 12 and the heat dissipation plate 11.

When a current is caused to flow in an opposite direction, the holes and electrons move in the opposite direction, and accordingly the heat exchanger plate 12 functions as the heat dissipation plate and the heat exchanger plate 11 functions as the heat absorption plate. Note that, in the example illustrated in FIG. 2, for the sake of description of a principle of the Peltier element 10, each of the numbers of illustrated layers in which the n-type thermoelectric material 15 and the p-type thermoelectric material 17 are stacked is only two. To allow practical heat dissipating/absorbing operations to be obtained, each of the n-type thermoelectric material 15 and the p-type thermoelectric material 17 are stacked in multiple layers.

By bringing either one of the heat exchanger plates 11 (12) of the thermoelectric module 13 that thus perform the heat dissipating/absorbing operations by being supplied with the current into contact with skin of the human body, it is possible to present a temperature stimulus.

(Human Body Detection Unit)

The human body detection unit 20 detects contact of a part of the human body with one of the heat exchanger plates 11 and 12 of the Peltier element 10 based on a change in the electrostatic capacitance between the heat exchanger plates 11 and 12.

As illustrated in FIG. 2, the heat exchanger plates 11 and 12 of the Peltier element 10 have the n-type thermoelectric materials 15₁ and 15₂, the p-type thermoelectric materials 17₁ and 17₂, and the like held therebetween to form an electrostatic capacitance Cp. One of electrodes of the electrostatic capacitance Cp is formed of the heat exchanger plate 11, while another of the electrodes of the electrostatic capacitance Cp is formed of the heat exchanger plate 12.

To both ends of the electrostatic capacitance Cp, e.g., the resistor R is connected. A change in a value of the electrostatic capacitance Cp can be detected based on, e.g., a change in an oscillation frequency f of the CR oscillation circuit that oscillates depending on the value (Cp) and a value of the resistor R.

A case where the human H touches one of the electrodes (e.g., the heat exchanger plate 12) of the electrostatic capacitance Cp with a fingertip is assumed. In that case, as illustrated in FIG. 1, an electrostatic capacitance Ch of the human body is connected in parallel to the electrostatic capacitance Cp of the Peltier element 10.

A combined capacitance of the electrostatic capacitance Cp of the Peltier element 10 and the electrostatic capacitance Ch of the human body begins to increase at a stage at which the human H brings the fingertip closer to the Peltier element 10 and becomes maximum when the human H touches, e.g., the heat exchanger plate 12 with the fingertip. A change in the combined capacitance can be detected based on the change in the oscillation frequency f of the CR oscillation circuit.

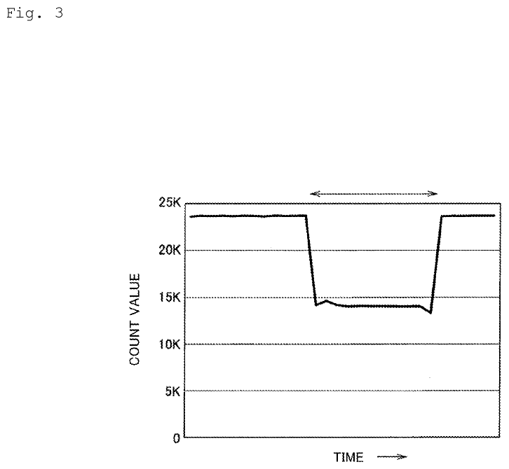

FIG. 3 is a diagram illustrating an example of the change in the oscillation frequency f when the heat exchanger plate 12 is touched by a finger. An abscissa axis in FIG. 3 represents time, while an ordinate axis therein represents a count value (10³: K) obtained by counting the oscillation frequency for a given period of time. Note that, even when the heat exchanger plate 11 is touched by the finger also, the same characteristic as that in FIG. 3 is obtained.

As illustrated in FIG. 3, two count values, i.e., a count value of about 23 K and a count value of about 13 K are obtained. The count value of about 23 K is a value obtained by counting the oscillation frequency f determined by an electrostatic amount value of only the electrostatic capacitance Cp of the Peltier element 10 and by the resistance value of the resistor R. The count value is obtained when the finger is not brought closer to the Peltier element 10.

Meanwhile, the count value of 13 K is a value obtained by counting the oscillation frequency f obtained when, e.g., the heat exchanger plate 12 is touched by the fingertip. Thus, it is possible to detect, based on the change in the oscillation frequency f, a state transition from a state where a part of the human body is brought closer to the Peltier element 10 to a state where the part of the human body comes into contact with the Peltier element 10.

Note that the CR oscillation circuit is a typical one. The change in the combined capacitance of the electrostatic capacitances Cp and Ch may also be detected by an oscillation circuit having another configuration which is referred to as an astable multi-vibrator or a ring oscillator.

(Temperature Stimulus Generation Unit)

The temperature stimulus generation unit 30 supplies a current to the Peltier element 10 when the amount of the electrostatic capacitance change between the heat exchanger plates 11 and 12 exceeds the threshold.

When the amount of the electrostatic capacitance change is detected based on, e.g., a change in the count value as illustrated in FIG. 3, the threshold is set to, e.g., 15 K. By doing so, it is possible to detect contact of a finger of the human body with, e.g., the heat exchanger plate 12.

When detecting the contact of the finger of the human body with the heat exchanger plate 12, the temperature stimulus generation unit 30 supplies a current to the Peltier element 10. Thus, the temperature stimulus presentation device 100 according to the present embodiment can present a temperature stimulus without requiring a component that detects the case where the temperature stimulus is required. In other words, the temperature stimulus presentation device 100 according to the present embodiment can detect the case where the temperature stimulus is required by using the Peltier element 10, and therefore it is possible to reduce the number of components.

Note that the temperature stimulus presentation device 100 can also detect a state before the finger touches the heat exchanger plate 12. As illustrated in FIG. 3, between the two count values, the count value varies at a gradient.

The gradient represents that, as the finger comes closer to the heat exchanger plate 12, the combined capacitance of the electrostatic capacitance Cp and the electrostatic capacitance Ch continuously increases. Accordingly, based on the change, the state before the finger touches the heat exchanger plate 12 can be detected.

In the case of the example illustrated in FIG. 3, the threshold of the count value is set to, e.g., 22 K. By doing so, the state before the fingertip touches the heat exchanger plate 12 can be detected. Note that the count value represents an amount of a change in an electrostatic capacitance value.

In other words, the threshold may also be set to the amount of the electrostatic capacitance change before a part of the human body comes into contact with the heat exchanger plate 11 or the heat exchanger plate 12. This allows the state before a finger touches the Peltier element 10 to be detected and can reduce a delay time until presentation of a temperature stimulus.

(Temperature Stimulus Presentation Method)

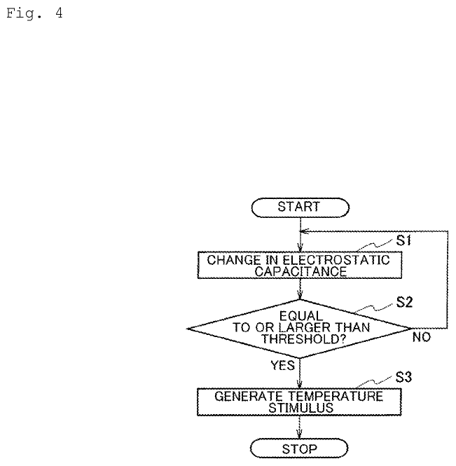

FIG. 4 is a flow chart illustrating a processing procedure in a temperature stimulus presentation method to be implemented by the temperature stimulus presentation device 100 according to the present embodiment.

The human body detection unit 20 detects contact of a part of the human body with the heat absorption plate 11 or the heat dissipation plate 12 of the Peltier element 10 based on a change in the electrostatic capacitance between the heat absorption plate 11 and the heat dissipation plate 12 (Step S1). The electrostatic capacitance change is detected based on the change in the count value obtained by, e.g., counting the oscillation frequency f as described above.

Next, the temperature stimulus generation unit 30 detects whether or not the amount of the electrostatic capacitance change exceeds the threshold (Step S2). When the amount of the electrostatic capacitance change is less than the threshold, Step S1 of detecting the electrostatic capacitance change is repeated (NO in Step S2).

When the amount of the electrostatic capacitance change exceeds the threshold (YES in Step S2), the temperature stimulus generation unit 30 supplies a current to the Peltier element 10. The Peltier element 10 supplied with the current presents, e.g., a cold stimulus to the human body via the heat dissipation plate 12 (Step S3).

Depending on setting of a threshold, it is also possible to supply the current to the Peltier element 10 before a part of the human body comes into contact with the heat dissipation plate 12.

Thus, the temperature stimulus presentation method according to the present embodiment is a temperature stimulus presentation method to be implemented by the temperature stimulus presentation device 100 and includes performing a human body detection step S1 of detecting contact of a part of the human body with the heat dissipation plate 12 or the heat absorption plate 11 of the Peltier element 10 based on the change in electrostatic capacitance between the heat dissipation plate 12 and the heat absorption plate 11, and a temperature stimulus generation step S3 of supplying a current to the Peltier element 10 when the amount of the electrostatic capacitance change exceeds the threshold (YES in Step S2). This allows a temperature stimulus to be presented with reduced power consumption and with a smaller number of components.

As has been described heretofore, with the temperature stimulus presentation device and the method therefor according to the present embodiment, it is possible to present a temperature stimulus presentation device that consumes reduced power and has a smaller number of components and a method therefor. Note that, depending on setting of the threshold, a state before a part of the human body comes into contact with the Peltier element 10 can be detected, and therefore it is possible to reduce a delay time until presentation of a temperature stimulus.

The description has been given by using a finger as an example of a part of the human body, but a part of the human body is not limited to this example. A part of the human body may be a back of a hand or a sole of a foot. Thus, a part of the human body is not limited to a fingertip.

While the example in which the amount of the electrostatic capacitance change is detected based on the count value obtained by counting the oscillation frequency f has been described, the detection need not necessarily be performed based on the count value. It may also be possible to measure a change in a magnitude of a combined capacitance of the electrostatic capacitance Cp of the Peltier element 10 and the electrostatic capacitance Ch of the human body. In other words, the amount of the electrostatic capacitance change may also be detected by a method other than a method using the oscillation frequency f.

The present invention naturally includes various embodiments which are not described herein and the like. Accordingly, the technical scope of the present invention should be determined only by the matters to define the invention in the scope of claims regarded as appropriate based on the description given above.

### INDUSTRIAL APPLICABILITY

The present invention is widely applicable in a field of virtual reality which makes a tactile presentation.

### REFERENCE SIGNS LIST

10 Peltier element
11 Heat dissipation plate (Heat exchanger plate)
12 Heat absorption plate (Heat exchanger plate)
13 Thermoelectric module
20 Human body detection unit
30 Temperature stimulus generation unit

1. A temperature stimulus presentation device that uses a Peltier element to present a temperature stimulus, the device comprising:
a human body detection unit that detects contact of a part of a human body with a heat dissipation plate or a heat absorption plate of the Peltier element based on a change in an electrostatic capacitance between the heat dissipation plate and the heat absorption plate; and
a temperature stimulus generation unit that supplies a current to the Peltier element when an amount of the electrostatic capacitance change exceeds a threshold.

2. The temperature stimulus presentation device according to claim 1, wherein the threshold is set to an amount of the electrostatic capacitance change before the part of the human body comes into contact with the heat dissipation plate or the heat absorption plate.

3. A temperature stimulus presentation method to be implemented by a temperature stimulus presentation device, the method comprising:
detecting contact of a part of a human body with a heat dissipation plate or a heat absorption plate of a Peltier element based on a change in an electrostatic capacitance between the heat dissipation plate and the heat absorption plate; and
supplying a current to the Peltier element when an amount of the electrostatic capacitance change exceeds a threshold.

4. The temperature stimulus presentation method according to claim 3, wherein the threshold is set to an amount of the electrostatic capacitance change before the part of the human body comes into contact with the heat dissipation plate or the heat absorption plate.
